(19) United States
(12) Patent Application Publication
(10) Pub. No.: US 2026/0228244 A1
(43) Pub. Date: Aug. 6, 2026

(54) APPARATUSES, SYSTEMS, AND METHODS FOR ASSISTED GENERATION OF LABEL SETS FROM GEOSPATIAL DATA AND MAP CONTEXT FOR LAYOUTS

(71) Applicant: Schneider Electric USA, Inc., Boston, MA (US)

(72) Inventor: Benjamin Vaughn Palmer, Windsor, CO (US)

(21) Appl. No.: 19/154,988

(22) PCT Filed: Feb. 13, 2024
(86) PCT No.: PCT/US2024/015648

§ 371 Date: Aug. 8, 2025

Related U.S. Application Data
(60) Provisional application No. 63/445,409, filed on Feb. 14, 2023.

(51) Int. Cl. G06F 16/29; G06F 16/28

(52) U.S. Cl. CPC G06F 16/29; G06F 16/287

(57) ABSTRACT

Apparatuses, systems, and methods are provided for providing assisted generation of label sets and providing information, including obtaining label definition information, selecting a subset of the label definition information, associating the subset of the label definition information with at least one scenario labeling set, providing a map view to a user, obtaining a selection of a chosen scenario labeling set of the at least one scenario labeling sets, determine placement of at least one label of the chosen scenario labeling set on the map view provided to the user, associating the at least one label with at least one attribute, and updating the map view responsive to the associating the at least one label with the at least one attribute.

### CROSS REFERENCE TO RELATED APPLICATION

The present application claims the benefit of and priority to U.S. Provisional Patent Application Ser. No. 63/445,409, filed on Feb. 14, 2023, and entitled APPARATUSES, SYSTEMS, AND METHODS FOR ASSISTED GENERATION OF LABEL SETS FROM GEOSPATIAL DATA AND MAP CONTEXT FOR LAYOUTS, which is incorporated by reference herein in its entirety.

### TECHNICAL FIELD

The present disclosure relates to providing assisted generation of labels sets for geospatial data and map context for layouts.

### BACKGROUND

Utility networks such as electric, gas, water, telecom, etc. may be designed and presented in geospatial information systems where multiple sources of information may be aggregated into a spatial representation on a map. This aggregate information can be used to aide in the design of the utility network. One challenge in leveraging a geospatial information system for designing utility networks is the effective presentation of information in artifacts, such as construction prints, outside of the system. Existing systems experience difficulties with label generation and associated content for information systems, such as geospatial information systems. These existing systems may permit generation of map labels as part of their respective utility design software systems. However, the processes for labeling generally fall into a manual or an automated process.

Geospatial information systems may be capable of aggregating data from multiple sources onto a spatial map representation. This capability may be valuable during the design of utility networks, such as electric, gas, water, and communication (e.g., telecom) systems where an optimal design may require the analysis and consideration of many different aspects of information from the surrounding geographic area. The resulting network design is typically conveyed to other parties through one or more visual representations, either digitally or through paper prints, outside of the geospatial information system. The network designer must take care in composing the layout of these visuals to provide the appropriate level of information and detail to the consumer from the vast underlying amount of data in the system. This manual process may suffer deficiencies with the time and costs associated with labeling each element by a user, and naturally lends itself to human error.

One facet of communicating information in geospatial visual representations is through labels placed in conjunction with symbols on the maps. Complex network designs may require multiple map views with different levels of detail and information exposed to effectively communicate to a consumer. In addition, complex designs may include congested areas which require careful label placement and spacing to ensure readability and clarity. Existing approaches to labeling these scenarios can consume a significant portion of the effort in composing a map layout.

Manual creation of map labels can be tedious, error prone, and may result in information that becomes stale or require rework when the data or map context changes. Automated label generation can address some of these limitations but may produce excessive labels, missing details, and poor placement, often resulting in additional cleanup work. This cleanup can be extensive, occasionally requiring more time than a manual process. Thus, automated processes may suffer problems with obtaining proper information and lack precision, as there is no correction for messy automated label information. For example, one or more errors associated with a label or element may be propagated many times over across an area or an entirety of geospatial data. This can lead to costly miscalculations caused by errors.

### SUMMARY

One or more implementations disclosed herein may overcome the above-identified deficiencies and other drawbacks associated with existing information systems. One or more implementations described herein may provide better balance and efficiency by integrating the strengths of both manual and automated processes into a new and novel process that is better suited for complex map design common to information systems, such as utility networks.

The present application includes examples of apparatuses, systems, and methods for providing assisted real-time generation of geographic map labels based on data categorization and analysis of related symbology, map characteristics, and user-driven label set options for efficient map layout in congested and multi-view scenarios that are common in utility network layouts.

In various example embodiments, a user may define zero, one, or more label definitions (e.g., the font characteristics, adornment, sizing, alignment, orientation, and/or contents of labels) for a classification of map data through a user interface. Some characteristics may be optionally defined to be driven by related data, symbology, and/or map state. Selection of a symbol within a map design may be used to assist in the creation of label definition by exposing available context information to the user. A user may be enabled to select a subset of label definitions into one or more scenario labeling sets. A preferred location of the label may be defined per label definition in some scenarios. A label priority may be defined to determine the order of placement per label definition in some scenarios. During the design process, a user may be enabled to select a label scenario set for a map view. A user may be allowed to opt for the system to automatically determine an initial location for labels and/or may manually place labels through interaction within the map.

Various operations for automated placement may be provided, such as when a user selects a user interface button to automatically place labels from a selected scenario label definition subset. For each visible symbol on the map, the related data may be used to determine a classification of the data. If the classification contains an applicable label definition in the active label definition set, that definition may be used to compose a label. Using the current state of the map, the size of the resulting label may be determined. A shape and an orientation of the associated symbol may be used to determine orientation of the label. The system may determine if the current layout contains sufficient open space to place the label at the desired location relative to the symbol, for example if the space is not open then one or more nearby locations may be searched until a location is found for label placement. Labels in the set (e.g., all labels or a subset thereof) may be placed by priority of the label(s).

Various operations for manual placement may additionally or alternatively provided. This may include a user moving the pointer icon (e.g., a mouse pointer) near a map symbol will present the highest priority label in the scenario set (e.g., label class) for the related map data if one has been defined in the set. A user may be enabled to toggle to another label definition related to the symbol if more than one label definition is defined for the related map data classification. If no label definition for the related symbol exists in the current scenario set, then no label will be presented in some embodiments. The label may be placed at a preferred location as defined by an associated label definition. Optionally, a mode may be toggled that allows the label to be offset to a user-defined location from the related symbol. Placement of a label through automated or manual means may create a relationship between the label and its associated symbol, data, and map to propagate changes. A placed label may be moved using a manual placement process flow. A placed label may be removed from the map by selecting it and deleting the label element. Updating the map scale or orientation may automatically update the orientation, size, and placement of map labels as defined by their respective label definitions in various embodiments. Some characteristics may be optionally defined to be driven by related data, symbology, or map state. Selection of a symbol within a map design may be used to assist in the creation of label definition by exposing available context information to the user

Various operations for automated placement may additionally or alternatively provided. A user may be enabled to select (e.g., click) a user interface button or element to automatically place labels from a selected scenario label definition subset. For each visible symbol on the map, at least a portion of related data may be used to determine a classification of the data. If the classification contains an applicable label definition in the active label definition set, that definition may be used to compose a label. Using the current state of the map, the size of the resulting label may be determined. A shape and an orientation of an associated symbol may be used to determine an orientation of the label. The system may determine if the current layout contains sufficient open space to place the label at the desired location relative to the symbol. If the space is not open, then nearby location may be searched until a location is found for label placement. In some embodiments, all labels in the set may be placed by priority of the label.

Implementations consistent with the present disclosure may enable map data to be categorized into a group classification. A user interface may be provided for the creation of a plurality of label definitions per group classification of map. A user interface may be provided for the grouping of label definitions into one or more scenario-based sets. Real-time feedback of labeling may be based on current scenario-based set and map context. Implementations consistent with the present disclosure may provide the ability to select an active label scenario set per map. Users may be provided with the ability to switch between labeling definitions for a classification within a scenario set. Assisted or automated placement and orientation of label elements may be provided according to aspects of the present disclosure. Automated label content and styling based on active label definitions and established relationships between label, symbol, data, and/or map may be provided. Implementations consistent with the present disclosure may enable determining and maintaining relationships between map data, symbology, and map context to label elements. Automated determination and update of label characteristics to reflect changes to symbol, data, or map. context based on established relationships may be provided. The ability to move and adjust generated labels after initial placement without breaking automated update behaviors may also be provided according to aspects of the present disclosure.

Implementations consistent with the present disclosure may enable vector-based prints. Construction prints may be generated according to one or more layouts described herein in the manner disclosed. Existing print issues relating to construction prints may be improved according to aspects described herein, for example in relation to increased speed, increased stability, reducing file sizes, and providing increased consistently in label placement, as compared to existing construction prints. This may be implemented, in whole or in part, using vector-based prints. Vector-based prints provide better control over label placement, better stability, introduction of vector-based graphics across an application, simplification of the number of symbol/label configurations needed, provide a smaller footprint for generated files (e.g., Adobe PDFs generated more quickly, such as in seconds), provide the ability to monitor memory usage, and permit the ability to implement undo/redo for layouts.

According to aspects of the present disclosure, provided is a method of providing assisted generation of label sets and providing information, including obtaining label definition information, selecting a subset of the label definition information, associating the subset of the label definition information with at least one scenario labeling set, providing a map view to a user, obtaining a selection of a chosen scenario labeling set of the at least one scenario labeling sets, determine placement of at least one label of the chosen scenario labeling set on the map view provided to the user, associating the at least one label with at least one attribute, and updating the map view responsive to the associating the at least one label with the at least one attribute. The at least one attribute may include one or more of symbol information, data, or mapping information. The method may include selectively enabling movement or deletion of the at least one label on the map view. The method may include updating an orientation, size, or placement of the at least one label defined by a respective label definition information when a scale or orientation of the map view is changed. The method may include generating a construction print corresponding to the updated map view.

According to further aspects of the present disclosure, provided is a device for providing assisted generation of label sets, the system including a processor, a memory, a communication section communicatively coupleable to the network, and an interface configured to enable one or more operations using the processor and the memory, including obtaining label definition information, selecting a subset of the label definition information, associating the subset of the label definition information with at least one scenario labeling set, providing a map view to a user, obtaining a selection of a chosen scenario labeling set of the at least one scenario labeling sets, determine placement of at least one label of the chosen scenario labeling set on the map view provided to the user, associating the at least one label with at least one attribute, and updating the map view responsive to the associating the at least one label with the at least one attribute. The at least one attribute may include one or more of symbol information, data, or mapping information. The interface may enable movement or deletion of the at least one label on the map view. The interface may further enable updating an orientation, size, or placement of the at least one label defined by a respective label definition information when a scale or orientation of the map view is changed.

According to still further aspects of the present disclosure, provided is a non-transitory computer-readable medium storing an information system program including instructions that, when executed by a processor of a device, causes the device to perform the operations of obtaining label definition information, selecting a subset of the label definition information, associating the subset of the label definition information with at least one scenario labeling set, providing a map view to a user, obtaining a selection of a chosen scenario labeling set of the at least one scenario labeling sets, determine placement of at least one label of the chosen scenario labeling set on the map view provided to the user, associating the at least one label with at least one attribute, and updating the map view responsive to the associating the at least one label with the at least one attribute. The at least one attribute includes one or more of symbol information, data, or mapping information. The non-transitory computer-readable medium may include one or more operations for selectively enabling movement or deletion of the at least one label on the map view. An orientation, size, or placement of the at least one label defined by a respective label definition information may be updated when a scale or orientation of the map view is changed. A construction print may be generated corresponding to the updated map view.

Numerous other objects, features, and advantages of the present invention will be readily apparent to those skilled in the art upon a reading of the following disclosure when taken in conjunction with the accompanying drawings.

### BRIEF DESCRIPTION OF THE DRAWINGS

A more detailed description of the disclosure, briefly summarized above, may be had by reference to various embodiments, some of which are illustrated in the appended drawings. While the appended drawings illustrate select embodiments of this disclosure, these drawings are not to be considered limiting of its scope, for the disclosure may admit to other equally effective embodiments.

FIG. 1 illustrates a partial block diagram illustrating an example environment useable according to aspects of the present disclosure.

FIG. 2 illustrates a block diagram of an embodiment of a client device according to aspects of the present disclosure.

FIG. 3 illustrates a partial block diagram of an embodiment of a server according to aspects of the present disclosure.

FIG. 4 illustrates a partial block diagram of an embodiment of an interface according to aspects of the present disclosure.

FIG. 5 illustrates a simplified block diagram of an embodiment of propagation of status updates according to aspects of the present disclosure.

FIG. 6 illustrates a simplified example of an embodiment of selecting an object and providing label information using a manual process according to aspects of the present disclosure.

FIG. 7 illustrates a simplified example of an embodiment of manually adjusting a label position according to aspects of the present disclosure.

FIG. 8 illustrates a block diagram of an embodiment of entity relationships between data, categorization, label definitions, and label sets according to aspects of the present disclosure.

FIG. 9 illustrates a partial example of a map interface and work location information according to aspects of the present disclosure.

FIG. 10 illustrates an example of a multi-view output of the system according to aspects of the present disclosure.

FIG. 11 illustrates examples of an interface useable with the systems described herein according to aspects of the present disclosure.

FIG. 12 illustrates an example of a configuration interface according to aspects of the present disclosure.

FIG. 13 illustrates a partial layout providing label information for a plurality of objects according to aspects of the present disclosure.

FIG. 14 illustrates a partial view of an example of an interface usable according to aspects of the present disclosure.

FIG. 15 illustrates a partial view of an example of an interface for customizing one or more layouts according to aspects of the present disclosure.

FIG. 16 illustrates a partial view of an example of an interface for customizing one or more layouts according to aspects of the present disclosure.

FIG. 17 illustrates as example of a callout associated with label information according to aspects of the present disclosure.

FIG. 18 illustrates an example of a partial multi-layout view of a work location according to aspects of the present disclosure.

FIG. 19 illustrates an example of a first interface view for manipulating object information according to aspects of the present disclosure.

FIG. 20 illustrates an example of a second interface view corresponding to FIG. 19, whereby the structure name has been changed according to aspects of the present disclosure.

Identical reference numerals have been used, where possible, to designate identical elements that are common to the figures. However, elements disclosed in one embodiment may be beneficially utilized on other embodiments without specific recitation.

### DETAILED DESCRIPTION

The present application describes to providing assisted generation of labels sets for geospatial data and map context for layouts.

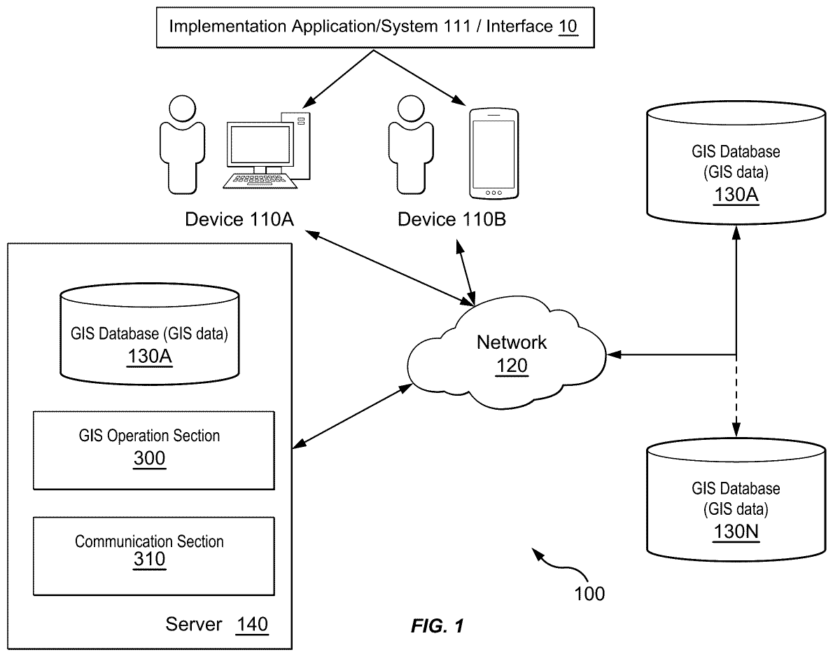

FIG. 1 illustrates a partial block diagram illustrating an example environment useable according to aspects of the present disclosure. As illustrated, the environment 100 comprises one or more client devices 110A, 110B (hereinafter client device 110 or device 110), a network 120 and one or more GIS databases 130A, 130B, 130N (hereinafter GIS database 130 or database 130). The client device 110 can be any hardware device that is able to establish a connection with another device or server, directly or via a communication network, for example network 120. Examples of a client device 110 include, but are not limited to: a desktop computer, a thin-client device, a mobile computing device such as a notebook, a laptop computer, a handheld computer, a mobile phone, a smart phone, a tablet, a phablet, and/or the like. The client device 110 typically includes one or more input/output devices to facilitate user interaction (e.g., to display a map or portion thereof, to enable a user to select an area or element on the map, to enable a user to select one or more elements or sub-elements, etc.).

In some embodiments, aspects of the disclosed system can be embodied in at least one implementation application/system 111 (hereinafter “interface 10”) which is installed or installable at the client device, and/or accessible in the client device 110 (e.g., via the network 120). The interface 10 can be downloaded from a server (e.g., server 140, an application store, and/or a repository) and may be installed or executable on the client device 110, in whole or in part. In some embodiments, the interface 10 can be and/or can access a web-based application or portal that can be accessed via a web-browser by one or more client device 110. Additionally or alternatively, the interface 10 may be a web-browser capable of accessing a remote website or data location, for example via the network 120. In some embodiments, the interface 10 can operate by utilizing data stored in the browser's local storage (e.g., network model data, utility information, component information, element information, and/or cached map data may remain in the client device 110 but the data may be periodically backed up in the host server or a cloud—for example via the network 120). The interface 10 may be a GIS software application useable according to aspects of the present disclosure.

The GIS database 130 (e.g., “database 130”) may be a database or file structure configured to store one or more objects (e.g., component(s)) defined in a geometric space. One example of a GIS database is a geodatabase. Typically, each utility maintains its own GIS database, although one or more GIS database 130 or portion thereof may be physically and/or logically separate from a particular utility. An example of a utility maintaining its own GIS database includes a gas company having its own GIS database that stores feature data for its gas distribution network. Similarly, an electric company or communications provider can have its own GIS database that stores feature data for its electric distribution or communication network. The GIS database 130 typically supports query execution on stored data as well as manipulation of the stored data. Examples of data stored in the GIS database include but are not limited to geometry or shape data and attributes of objects, typically grouped into different feature classes. Additionally or alternatively, a database 130 may be any repository configured to store one or more sets of data, without being specifically limited to GIS data. The GIS database 130 or portion thereof may be implemented in Microsoft SQL Server, PostgreSQL relational database management systems, Microsoft Access, Oracle, IBM DB2, IBM Informix, and/or the like. Additionally or alternatively, the GIS database 130 or portion thereof may be implemented via one or more storage systems, for example implemented by a cloud computing platform or environment, or by any distributed storage system, including Microsoft Azure.

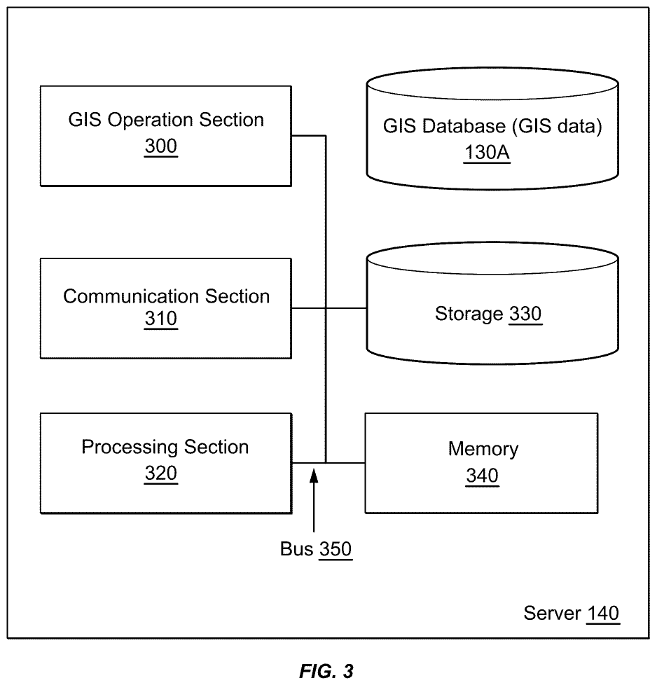

In some embodiments, the environment 100 includes a server 140 (e.g., computing device). The server 140 may include the GIS database 130 (e.g., GIS database 130A), a GIS Operation Section 300, and/or a Communication Section 310. The GIS Operation Section 300 and the Communication Section 310 are described hereinbelow with reference to FIG. 3. The server 140 may be communicatively coupleable to one or more device 110 and/or one or more GIS database 130B, 130N, for example via the network 120.

The network 120, over which the client device(s) 110, the one or more GIS database(s) 130, and the server 140 can communicate may be a telephonic network, an open network, such as the Internet, or a private network, such as an intranet and/or the extranet. The network 120 can be any collection of distinct communication networks operating wholly or partially in conjunction to provide connectivity to the client device(s) 110 and the GIS databases 130 and may appear as one or more communication networks to the serviced systems and devices. In some embodiments, communications can be achieved by a secure communications protocol, such as secure sockets layer (SSL), or transport layer security (TLS).

In addition, communications can be achieved via one or more wireless networks, such as, but not limited to, one or more of a Local Area Network (LAN), Wireless Local Area Network (WLAN), a Personal area network (PAN), a Campus area network (CAN), a Metropolitan area network (MAN), a Wide area network (WAN), a Wireless wide area network (WWAN), Global System for Mobile Communications (GSM), Personal Communications Service (PCS), Digital Advanced Mobile Phone Service (D-Amps), Bluetooth, Wi-Fi, Fixed Wireless Data, 2G, 2.5G, 3G, 4G, 4G-LTE networks, enhanced data rates for GSM evolution (EDGE), General packet radio service (GPRS), enhanced GPRS, messaging protocols such as, TCP/IP, SMS, MMS, extensible messaging and presence protocol (XMPP), real time messaging protocol (RTMP), instant messaging and presence protocol (IMPP), instant messaging, USSD, IRC, or any other wireless data networks or messaging protocols.

One or more client device(s) 110 can be coupled to the network 120 (e.g., Internet) via a dial up connection, a digital subscriber loop (e.g., DSL, ADSL), cable modem, fiber optic, and/or other types of connection. Thus, the client device(s) 110 can communicate with remote servers (e.g., one or more of a server 140, a GIS database 130, a mail server, an instant messaging server, etc.), some of which may provide access to user interfaces of the World Wide Web via a web browser, for example.

The client device 110 may function in various embodiments as a thin client device which obtains at least a portion of data from a server 140 for operation (e.g., GIS data). The client device 110 may be operable to cache/store the at least a portion of data from the server 140 for presentation to a user of the client device 110, for example viewable via a mapping interface displayable to the user and which enables the user to view and/or perform one or more actions in association therewith. The client device 110 may be configured to obtain the at least a portion of data from the server 140, to display the at least a portion of data from the server 140 to a user of the client device 110, to receive at least one input command or operation from the user in relation to the at least a portion of data, and to transmit to the server 140 a representation of the at least one input command or operation.

A user of the device 110 may be enabled to generate, modify, and/or remove one or more label definitions or component(s) thereof. The device 110 may be configured to store one or more label definitions or representation(s) thereof at the memory 114 and/or the storage 118. Additionally or alternatively, one or more label definitions or representation(s) thereof may be selectively transmitted from the device 110, for example via the communication section 116 via the network 120 to one or more other elements, such as a server 140 and/or GIS database 130. The one or more label definitions may be viewable and/or usable via an interface associated with the device 110, for example the interface 10. The label definitions may be accessed and/or editable by a user of the device 110. In various embodiments, an administrator may be enabled to generate, modify, and/or remove one or more label definitions or subsets thereof, and access to one or more operations and/or sets of data may be access-limited, for example to administrators. In various embodiments described herein, a label definition may be a user-specified grouping of one or more label style and one or more content definition. As previously noted, label definitions or subsets thereof may be stored, either in whole or in part, at the device 110, at the server 140, and/or at the GIS database 130, or combination(s) thereof.

As described herein, during operation a user of a device 110 may define zero, one, or more label definitions (the font characteristics, adornment, sizing, alignment, orientation, and contents of labels) for a classification of map data through a user interface) via the interface 10 of the device 110. Some characteristics may be optionally defined to be driven by related data, symbology, or map state. Selection of a symbol within a map design may be used to assist in the creation of label definition by exposing available context information to the user. A user of the device 110 may selects a subset of label definitions into one or more scenario labeling sets (e.g., label class(es)/classification(s)).

A preferred location of the label may be defined per label definition in a scenario. A label priority may be defined to determine the order of placement per label definition in a scenario. The label definition may be stored, for example, either in whole or in part at the device 110, at the server 140, and/or at a GIS database 130, or combination(s) thereof. During the design process, a user of the device 110 selects a label scenario set for a map view provided by the interface 10. The user of the device 110 may opt for the system to automatically determine an initial location for labels or may manually place labels through interaction within the map using the interface 10.

For the user of the device to select automated placement the user may select (e.g., via a mouse click) a user interface button at the interface 10 to auto-place labels from a selected scenario label definition subset (e.g., including one or more previously created label definitions previously). For each visible symbol on the map, the related data is used to determine the classification of the data. If the classification contains an applicable label definition in the active label definition set, that definition is used to compose a label for the symbol. One or more properties of the resulting label such as a label or text size may be determined using the current state of the map. A shape and orientation of the associated symbol may be used to determine orientation of the label and/or text. The system may determine if the current layout contains sufficient open space to place the label at the desired location relative to the symbol. If the space is not open, then nearby locations may be searched until a location is found for label placement. The system may ensure that all labels in the set are placed in accordance with a respective priority of the labels.

A user of the device 110 may be enabled to provide manual placement of labels. This may include a user of the device 110 moving a selector such as a mouse pointer near a map symbol which will cause the interface 10 to present the highest priority label in the scenario set for the related map data if one has been defined in the set. The user of the device 110 may toggle to another label definition related to the symbol if more than one label definition is defined for the related map data classification. If no label definition for the related symbol exists in the current scenario set, then no label will be presented to user of the device 110 by the interface 10. The label may be placed at a preferred location as defined by associated label definition. Optionally, a mode made be toggled that allows the label to be offset to a user-defined location from the related symbol. This may include permitting a user do indicate a preferred placement of the label, for example by dragging the label on the map, by clicking a preferred location, or by other means of indicating a preferred label location (for example, using the I/O Section 124).

Placement of a label through automated or manual means will create a relationship between the label and its associated symbol, data, and map to propagate changes. This relationship between the label and its associated symbol, data, and map may be optionally stored, in whole or in part, at the device 110, the server 140, and/or the GIS database 130 or combination(s) thereof. The association may additionally or alternatively be propagated across the system. Once a label has been placed, either by the automated or manual placement process, the label may be moved using the flow described in the manual placement process. A placed label may be removed from the map by a user of the device 110 selecting it and deleting the label element. Updating the map scale or orientation may cause the system to automatically update the orientation, size, and placement of map labels as defined by their respective label definitions (e.g., at the interface 10). The system may update the underlying map data or symbology with automatically updated characteristics, contents, and placement of the label as defined by their respective label definitions.

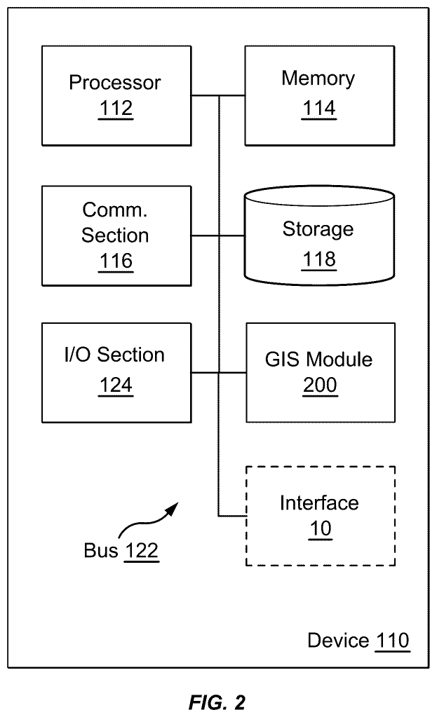

FIG. 2 illustrates a block diagram of an embodiment of a client device 110 according to aspects of the present disclosure. A client device 110 (e.g., a device 110) may include one or more of a processor 112, a memory 114, a communication section 116, a storage 118, an input/output (I/O) section 124, a GIS module 200, and/or an interface 10. One or more of the processor 112, memory 114, communication section 116, storage 118, I/O section 124, GIS module 200, and/or interface 10 may be communicatively coupled or coupleable to one another via a conductive bus 122. Although illustrated as part of a device 110, it should be appreciated that one or more of the processor 112, memory 114, communication section 116, storage 118, I/O section 124, GIS module 200, and/or interface 10 may be physically and/or logically separate from the device 110. For example, one or more of the processor 112, memory 114, communication section 116, storage 118, I/O section 124, GIS module 200, and/or inerface 10 may be accessed by the device 110 over a communications medium such as network 120, either in whole or in part.

The processor 112 may by any hardware and/or software processor, for example one or more hardware processor such as an Intel® Pentium-type processor, a Motorola® PowerPC, a Sun® UltraSPARC®, a Hewlett-Packard® PA-RISC processors, or any other type of hardware processor. Additionally or alternatively, the processor 112 may be or include one or more virtual or software processors configured to perform at least one operation described herein. The memory 114 may be a volatile, random-access memory such as a dynamic random-access memory (DRAM) or static memory (SRAM), and/or may be or include at least one non-volatile memory. The communication section 116 may be any wired and/or wireless communication elements configured to permit the device 110 to communicate, for example via the network 120. The storage 118 may be configured to store one or more sets of information useable by or in association with the device 110. For example, the storage 118 may be configured to store one or more sets of instructions executable by the processor 112 to perform one or more operations. Additionally or alternatively, the storage 118 may be configured to store one or more sets of data used by and/or useable in association with the GIS module 200 and/or interface 10.

The I/O section 124 may be any input and/or output element useable by or in conjunction with the device 110. For example, the I/O section 124 may include one or more display unit or controller configured to permit output to a user. Output may include any visual, audio, audiovisual, tactile, or any other form of perceptible information by a user or group of users. Additionally or alternatively, the I/O section 124 may include one or more input units, such as a keyboard, a mouse, a trackpad, a trackball, or any other element capable of receiving an input from a user or group of users associated with the device 110.

The device 110 may include a GIS module 200. The GIS module 200 may include one or more applications, data sets, interfaces, modules, and/or elements configured to provide or to assist in providing one or more GIS operations or services by or in conjunction with the device 110. In various embodiments, the GIS module 200 may include or be associated with the interface 10 and/or elements thereof. For example, the GIS module 200 may include an application or portal configured to perform one or more operations described herewith with reference to the interface 10, either alone or in conjunction with a communicatively coupleable element such as a server, data store, or other source of information and/or metadata.

FIG. 3 illustrates a partial block diagram of an embodiment of a server according to aspects of the present disclosure. The server 140 may include one or more of a GIS operation section 300, a communication section 310, a processing section 320, a storage 330, a memory 340 and/or a GIS database 130A. One or more of the GIS operation section 300, the communication section 310, the processing section 320, the storage 330, the memory 340, and/or the GIS database 130A may be communicatively coupled or coupleable to one another via a conductive bus 350. The GIS operation section 300 may include one or more modules, executables, sections of code, interface, and/or other hardware or software elements configured to perform or enable one or more GIS operations to be performed by the server 140 or in conjunction with the server 140. The GIS operation section 300 may be configured to transmit at least a portion of data associated with the GIS database 130A to a device 110 via the network 120. This may permit the device 110 to view and/or operate on the at least portion of data and to provide one or more command or operation using an interface 10 of the device 10. The GIS operation section 300 may be configured to receive the one or more commands or operations and to coordinate one or more corresponding operations.

The processing section 320 may by any hardware and/or software processor, for example one or more hardware processor such as an Intel® Pentium-type processor, a Motorola® PowerPC, a Sun® UltraSPARC®, a Hewlett-Packard® PA-RISC processors, or any other type of hardware processor. Additionally or alternatively, the processing section 320 may be or include one or more virtual or software processors configured to perform at least one operation described herein. The memory 340 may be a volatile, random-access memory such as a dynamic random-access memory (DRAM) or static memory (SRAM), and/or may be or include at least one non-volatile memory. The communication section 310 may be any wired and/or wireless communication elements configured to permit the server 140 to communicate, for example via the network 120. The storage 330 may be configured to store one or more sets of information useable by or in association with the server 140. For example, the storage 330 may be configured to store one or more sets of instructions executable by the processing section 320 to perform one or more operations. Additionally or alternatively, the storage 330 may be configured to store one or more sets of data used by and/or useable in association with the GIS operation section 300, the GIS module 200, and/or interface 10. In various embodiments, the storage 330 may be configured to store at least a portion of GIS data useable by the GIS operation section 300, and/or the GIS database 130A.

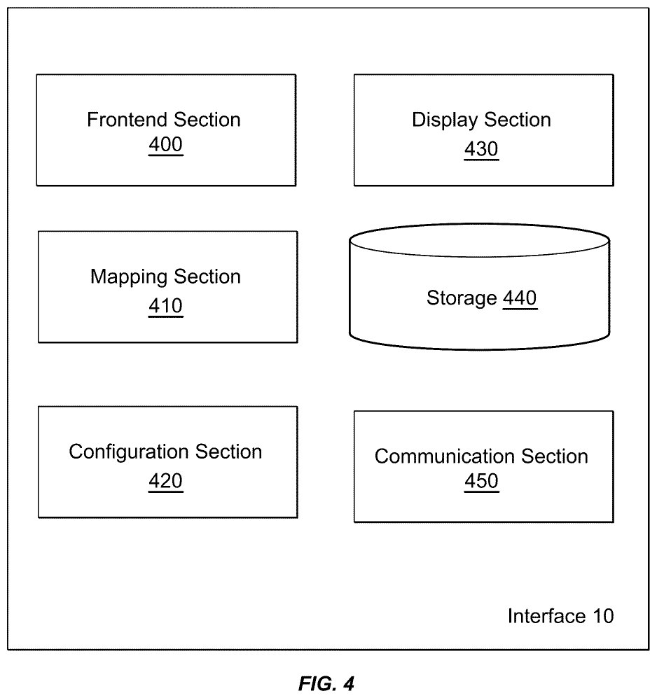

FIG. 4 illustrates a partial block diagram of an embodiment of an interface according to aspects of the present disclosure. The interface 10 may be a GIS software application in various embodiments which may either be installed at or otherwise accessible to one or more device 110 (e.g., e.g., using a web browser via the network 120). An interface 10 may include one or more of a frontend section 400, a mapping section 410, a configuration section 420, a display section 430, a storage 440, and/or a communication section 450. The frontend section 400 may be any executable, data set, metadata, module, code portion, instruction(s), or information locally accessible at a device operating or assisting in operating the interface 10. A mapping section 410 may enable one or more mapping operations, for example corresponding to at least one geographic map or subset thereof in conjunction with one or more objects (e.g., components) or elements associated therewith. For example, the mapping section 410 may be configured to provide or assist in providing object data in relation to geographic location information which may be viewed, accessed, modified, added, changed, updated, and/or deleted, for example using the display section 430. The display section 430 may include one or more hardware and/or software elements capable of displaying or assisting in displaying one or more sets of data or information in relation to the interface 10. This may include, for example, one or more hardware devices or software elements such as drivers to permit a user of a device associated with the interface 10 to view GIS data and to optionally perform one or more operations associated with GIS data, for example using a graphical user interface associated with the interface 10 via a device 110. Although described with reference to display, it should be appreciated that the display section 430 may provide one or more hardware and/or software elements for obtaining or assisting in obtaining input from a user associated with the interface 10. In various embodiments, a combination of the mapping section 410 and the display section 430 may combine to form aspects of a mapping interface as described herein.

The storage 440 may be provided to store or assist in storing one or more sets of GIS data and/or one or more sets of data useable by the interface 10 perform one or more operations described herein (e.g., in embodiments where the interface 10 is either wholly or partially separate from a device 110). In various embodiments the storage 440 may include a memory configured to cache/store at least a portion of data received from a server 140, for example at least a portion of GIS data viewable and/or usable by the device 110 for presentation to a user via the display section and which permits a user of the device 110 to view and/or provide at least one input command or operation in association with one or more elements of the at least a portion of data.

The configuration section 420 may provide one or more hardware and/or software elements configured to enable the interface 10 to perform at least one operation described herein. Additionally or alternatively, the configuration section 420 may include one or more sets of configuration data, for example to assist in operation of the interface 10. This may include one or more sets of configuration data to enable the interface 10 to transmit one or more input command or operations from the device 110 to a server 140. In various embodiments this may be accomplished by maintaining or obtaining communication information relating to one or more servers 140 or communications elements or maintaining or obtaining one or more locations for obtaining communication information for publishing commands and/or operations (e.g., network address information, remote broadcast location, server information, or the like) or object information or metadata relating thereto, for example. The communication section 450 may be any wired and/or wireless communication elements configured to permit the interface 10 to communicate, for example via the network 120.

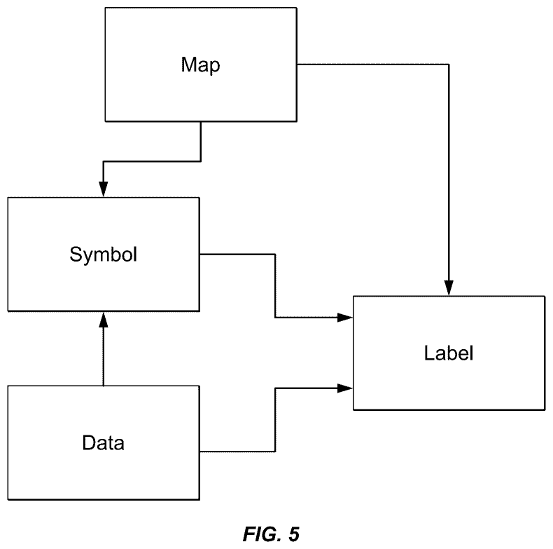

FIG. 5 illustrates a simplified block diagram of an embodiment of propagation of status updates according to aspects of the present disclosure. As illustrated by FIG. 5, each of map information, symbol information, and data may be provided as or in conjunction with label information. Map information may include geographic and/or geospatial information useable as described herein. Symbol information may include one or more map symbols associated with the map information. Data illustrated by FIG. 5 may include underlying network or building information in various embodiments. Additionally or alternatively, the data of FIG. 5 may optionally include cost information and/or one or more work parameters or attributes. Label information may include information relating to one or more elements or components, for example information relating to a material, identification of a feeder, a three-base conductor, or any other physical or virtual element associable with map and/or symbol information in conjunction with the map information. At least a portion of the map information, the symbol information, the data, and/or the label information may be stored, for example, at one or more of a server 140, a device 110, and/or one or more database 130, either in whole or in part. In various embodiments, the label information may be configured to be stored locally at a device 110. Additionally or alternatively, at least one set of label information may be configured at a device 110 and either in real-time or subsequently transmitted to one or more server 140 and/or database 130. As reflected by FIG. 5, map information may be used to propagate state information for both symbol information and label information. Similarly, data may be used to propagate state updates for both symbol information and label information. Each of map information, symbol information data state updates may be propagated to label information useable according to aspects described herein.

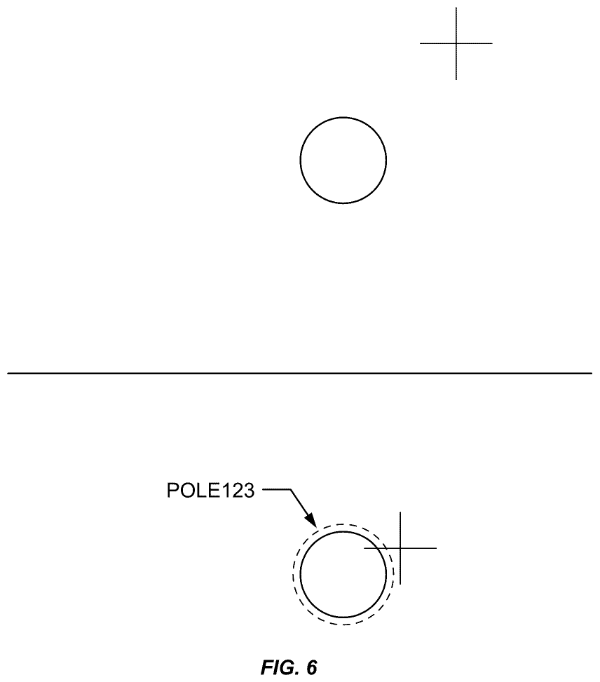

FIG. 6 illustrates a simplified example of an embodiment of selecting an object (e.g., component) and providing label information using a manual process according to aspects of the present disclosure. A selector such as a mouse pointer (illustrated as a crosshair in FIG. 6) may be positioned by a user over an object (e.g., symbol). This may be done by a user of a device 110, for example using the I/O Section 124. The upper portion of FIG. 6 depicts the selector to the upper right away from the circular object, while the bottom portion of FIG. 6 illustrates the selector having selected the object, for example by a user clicking a mouse button while over or adjacent to the object on a visual interface, such as a map interface. The label information POLE123 may then be generated and displayed on the map interface, for example with an arrow. The content of the label data may be selectively modified and/or configured in prior to selection of the object and/or in real-time during or after selection of the object (for example by initially being presented with preferred data and permitting a user of the device 110 to modify what label information is to be presented). This may be done by a user of a device 110 described herein. The label information provided upon selection of the object may be or include or be associated with a subset of map information. symbol information, data, and/or label information described herein. The subset of map information symbol information, data, and/or label information may be associated with at least one label definition. At least one parameter associated with the label information and/or object may be provided and/or modified by a user and saved as part of the label information and/or separately from the label information. The at least one parameter may be used to selectively update existing label information, to preconfigure future label information, either locally, at the database 130, and/or in relation to one or more sets of map information, symbol information, data, and/or label information described herein. One or more corresponding label definition may be selectively saved or modified responsive to updating the existing label information.

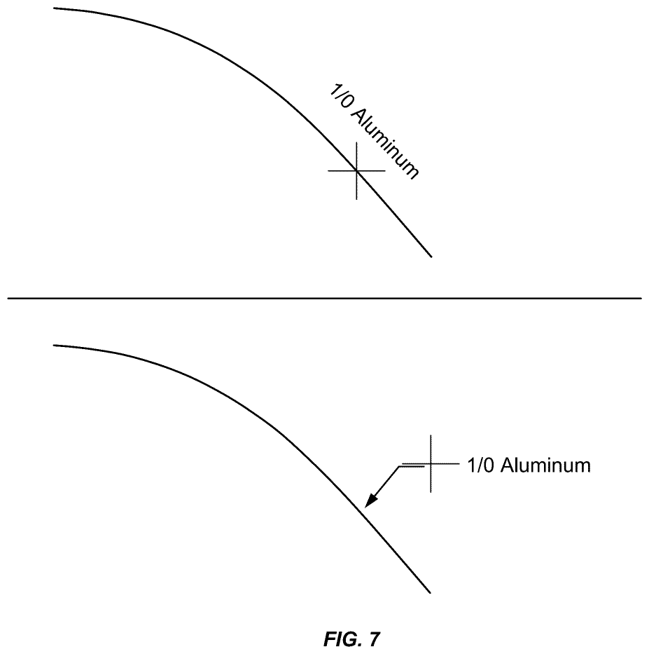

FIG. 7 illustrates a simplified example of an embodiment of manually adjusting a label position according to aspects of the present disclosure. FIG. 7 illustrates a cable and a label associated with the cable, both before and after a user manipulation of a placement of the label, for example using the interface 10 of the device 110. The label information “1/0 Aluminum” associated with the cable object may be selected by a user of a device 110, for example using a mouse pointer thereof, and the placement of the label information may be moved, for example by clicking and dragging. An indication element such as an arrow may be automatically generated as the label information is moved or after the label information is moved to clearly identify the relationship between the label information and the object. The preferred label placement may be propagated by the system and may be selectively stored, in whole or in part, by the device 110, the server 140, and/or the GIS database 130, or combination(s) thereof.

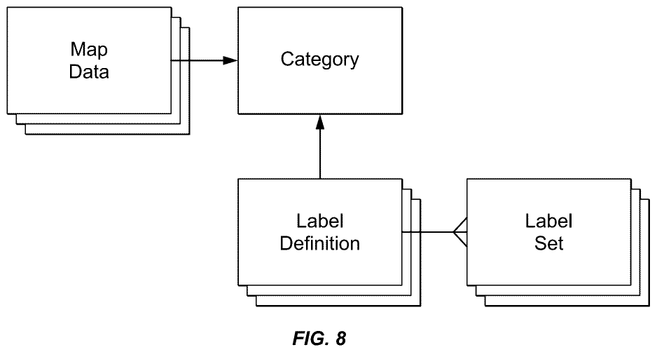

FIG. 8 illustrates a block diagram of an embodiment of entity relationships between data, categorization, label definitions, and label sets according to aspects of the present disclosure. As illustrated by FIG. 8, a plurality of map data may relate to one or more category. A plurality of label sets of be associated with one or more label definitions. The one or more label definitions may be associated with one or more categories.

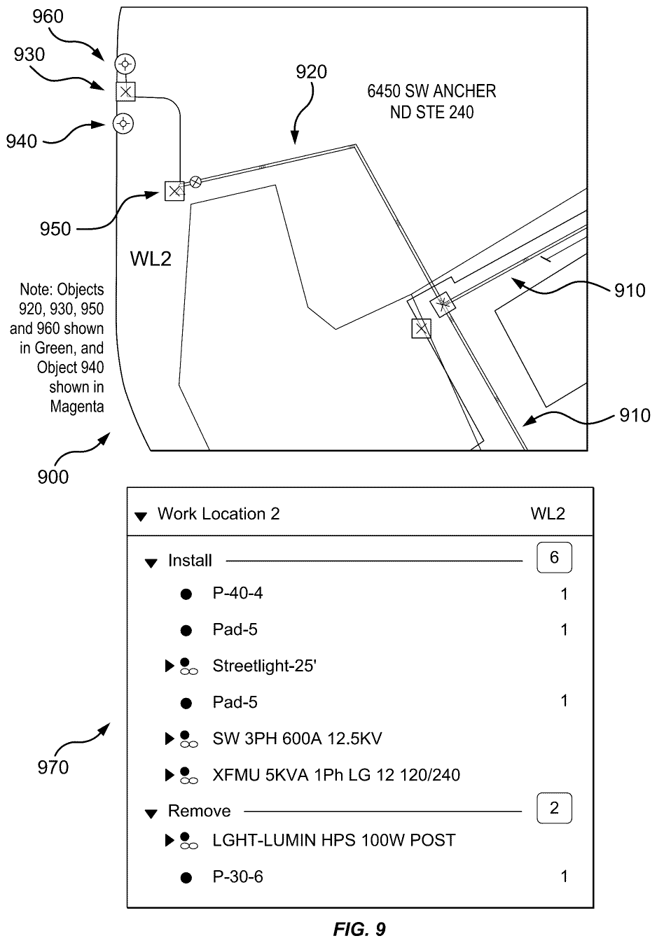

FIG. 9 illustrates a partial example of a map interface and work location information according to aspects of the present disclosure. The interface 900 may correspond to at least a portion of an interface 10 and may include existing infrastructure 910, work infrastructure 920, a first object 930, a second object 940, and/or a third object 950. The existing infrastructure 910 may include one or more current or existing objects or elements visually conveyed or conveyable on a visual display associated with the interface 10, for example at a device 110. A work infrastructure 920 may include on or more object or elements configured to be installed, modified, or removed. This may include, for example, a conductor extending from the existing infrastructure 910 and selectively associated with one or more objects (e.g., the first object 930, second object 940, a third object 950, and/or a fourth object 960 of FIG. 9). At least a portion of the work infrastructure 920, such as one or more objects (e.g., symbol(s) representing one or more objects) may be manually and/or automatically placed by the GIS system and may correspond to a work location in some embodiments. As shown by menu 970, a work location may include one or more operations, such as an install operation and a remove operation, although additional or alternative operations may be associated with a work location without departing from the spirit and scope of the present disclosure. As shown at menu 970, a work location may include a plurality of objects, and may be optionally mapped to one or more operations, such as an install operation or a removal operation.

One or more objects (e.g., as one or more symbols representative thereof) shown on the interface 900 may be visually distinguishable according to an attribute or property of the object or a group of objects. A type or format of visual distinction may be predetermined or may be customizable by a user. Symbols may be color coded according to an attribute of the object, an operation associated with the object, a parameter associated with the object, an attribute or operation associated with a work location, or the like. For example, the second object 940 may be a utility pole to be removed at a work location and may have a different visual distinguishing attribute of the representative symbol thereof on the interface 10, such as a magenta coloring to represent a removal operation. In contrast, the first object 930 and the third object 950 may be pedestals coupled to a conductor to be installed running from the existing infrastructure 910 to support the fourth object 960, which may be a new utility pole to be installed, the symbols of each of which may be visually distinguished from the second object 940, for example by being displayed using a green color by the interface 10. Although described with reference to color, it should be appreciated that other means of visual distinction may be used, such as dashing lines, line thickness, etc., without departing from the spirit and scope of the present disclosure. In various embodiments, one or more visually distinguishing attributes and/or sets of information may be selected and/or modified by a label definition associated with an object/symbol. For example, a magenta color may be specified in a label definition for a removal option, and the magenta color may be applied to a label (e.g., as a text color) for an object/symbol associated with the removal operation.

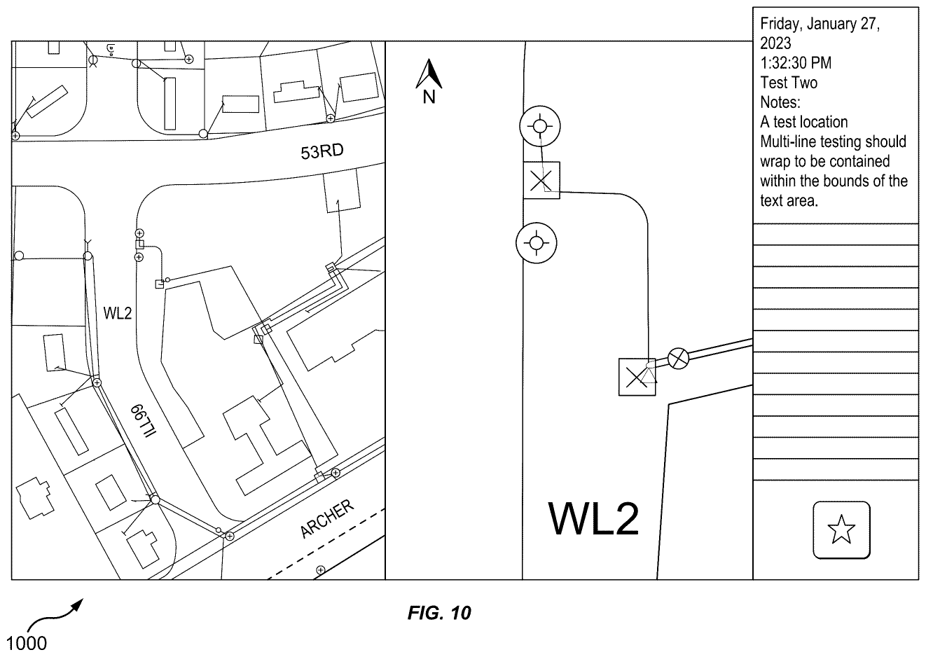

FIG. 10 illustrates an example of a multi-view output of the system according to aspects of the present disclosure. The output 1000 may include a plurality of map views (e.g., layouts/perspectives), such as two map views as illustrated by FIG. 10, although any number of views may be used without departing from the spirit and scope of the present disclosure. The output 1000 may be or may represent a construction print in various embodiments, which may be provided to a crew to carry out one or more operations illustrated by the output 1000. Each view (e.g., layout) of the output 1000 may include the same or subset of the same map and/or label data, and may be enabled to convey different views, attributes, properties, appearance, and/or label information for one or more objects or elements of at least a portion of map information. This may include different view orientations, zoom levels, visualized objects, etc. Although described with reference to map information, it should be appreciated that one or more views provided by the output 1000 may relate to any two-dimensional, three-dimensional, or other representation of any object, group of objects, or visual representations, and should not be viewed as being limited only to map information.

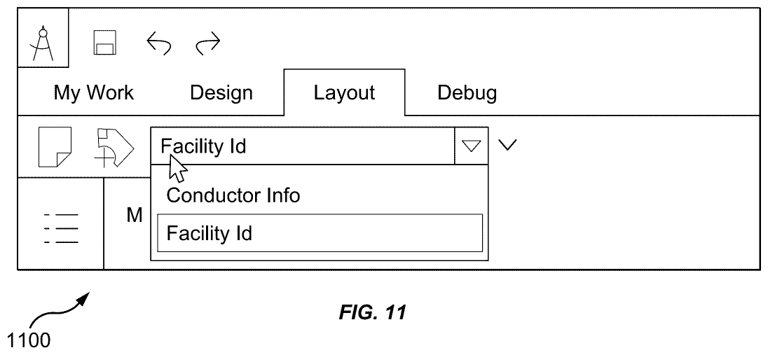

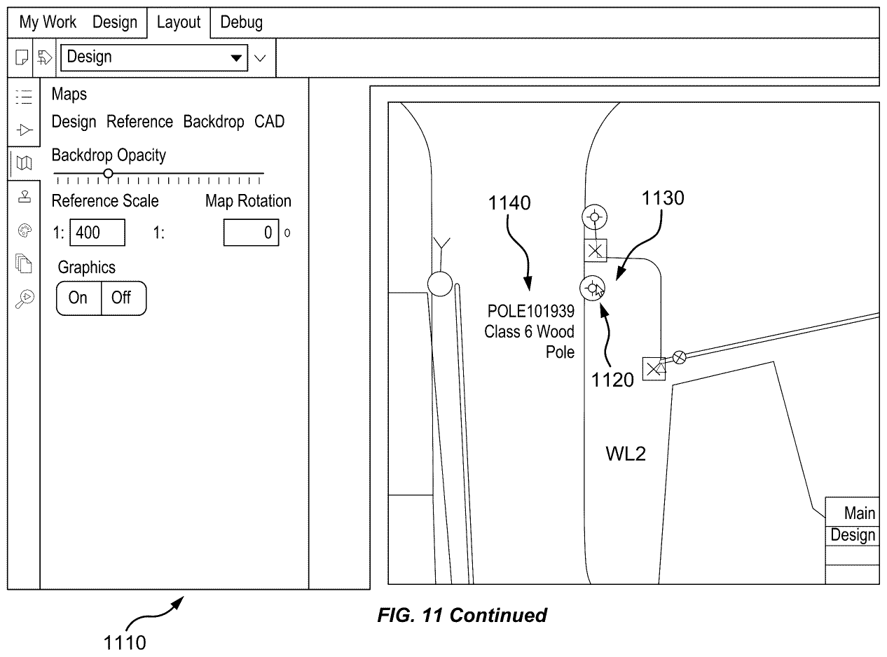

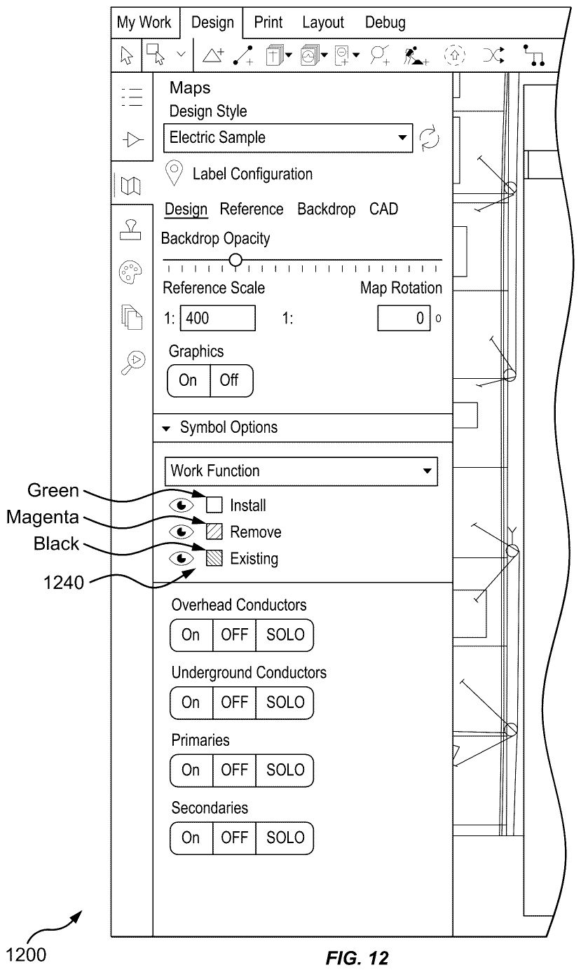

FIG. 11 illustrates examples of an interface useable with the systems described herein according to aspects of the present disclosure. The interfaces 1100 and 1110 are examples of user interfaces usable according to various embodiments, for example as provided by the interface 10. The interface 1100 reflects a menu of user-selectable label sets (e.g., scenario labeling sets) including one or more label definitions or subsets of label definitions according to aspects of the present disclosure. Each label set may correspond to a component class and/or one or more label definitions in various embodiments. One or more label sets or elements thereof may be created, modified, and/or deleted via the interface 10, for example by an administrator. An edit button or section may be provided for a user to access label set information and to create/modify/delete one or more sets of information relating thereto. Although illustrated with two label sets in FIG. 11, Conductor Info and Facility id, it should be appreciated that the menu or an alternatively selection element may be used to identify and select any number of user-defined and/or system-defined label sets. Using a selected label set, a user may interact with the interface 1110 to select one or more objects, such as object 1130 to display label information 1140.

A user of a device 110 may be enabled to select what label information, label attributes, or characteristics may be displayed in conjunction with the label information 1140. A selected label set may provide a default map view, size, font size, shape, or color, and/or any option(s) which may contribute to the visual appearance and information associated with a layout or group of layouts. In various embodiments, a user of the interface 1110 may be provided with a visual indication when they select an object, symbol, or component to see what options are available for placement and information associated with the object, symbol, or component. A user may select an object (e.g., by clicking on a symbol representing the object via the interface 10) to be present label information corresponding to the selected object. The user may be permitted to select which information or lack of information to be included on the layout, as well as to determine a placement and/or orientation of the label information a respective layout. In various embodiments, user determination of information content, placement, orientation, or other attribute may be saved and may optionally be used to propagate across existing data or to be used a default setting for future instances of an object/symbol or set of label information. Implementations consistent with the present disclosure may be such that a visual orientation of at least a portion of the label information may be configured to maintain a particular configuration relative to an orientation of map information presented via interface 10. This may include adjusting an orientation of the label information such that the text of the label information maintains a vertical orientation relative to a particular layout/view where possible.

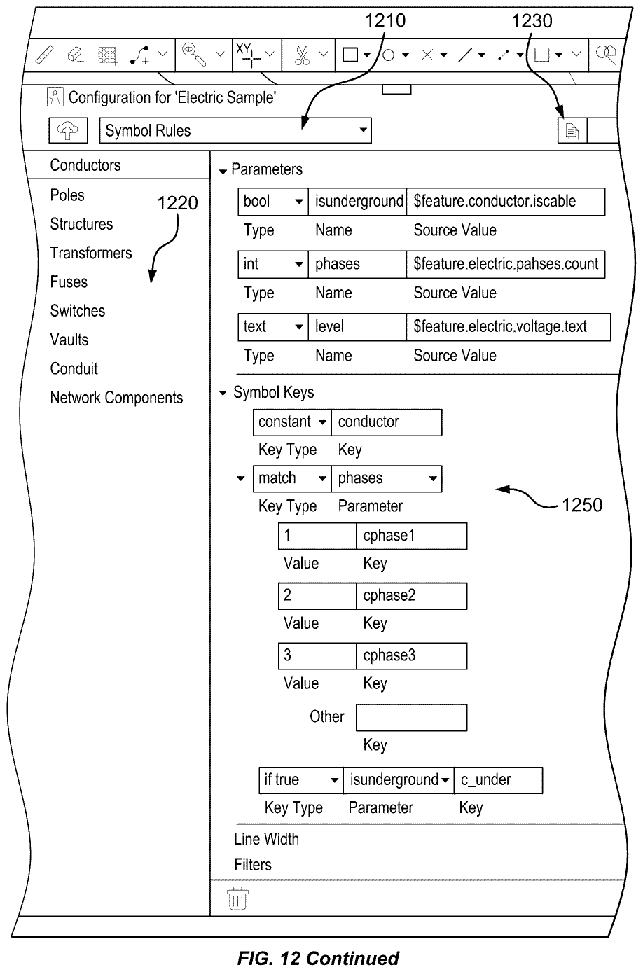

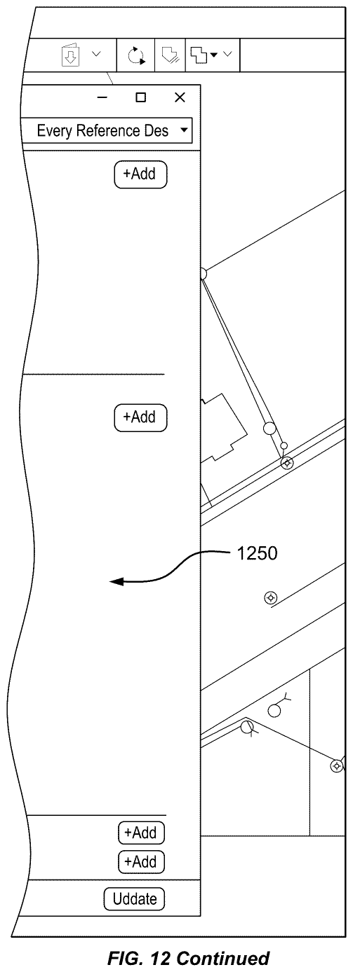

FIG. 12 illustrates an example of a configuration interface according to aspects of the present disclosure. The configuration interface 1200 includes one or more of a dialog 1210, a component section 1220, a menu 1230, a symbol operation section 1240, and/or a parameter section 1250. The dialog 1210 may be used for label settings configuration. Switching between symbol and label configuration may be accomplished by changing the view in this menu (e.g., as a drop-down menu). The component section 1220 enables configuration to be performed per data categorization. In an electric network, this categorization may be by component type such as conductors, fuse, transformer etc. This same categorization may be used in one or more label configurations. The menu 1230 may be configured to show administrative configuration for symbols and/or labels. Although the mockup demonstrated symbology configuration, label workflows may be implemented in a similar manner. The drop down in the upper-right corner may allow switching between different named configurations. The symbol operation section 1240 may enable a non-administrator to have options for controlling some characteristics of the configuration at runtime, as determined by an administrator. This view shows options for changing symbology, but the options for selection of labeling sets and toggling between automated and assisted label generation may be accomplished in a similar place in various embodiments. The parameter section 1250 may provide one or more options for symbol and/or label configuration which may be done in a similar manner where information from the various sources of data in the geospatial information system can be assigned to variables, which can then be used to shape the characteristics or content of the symbol(s) and/or label(s).

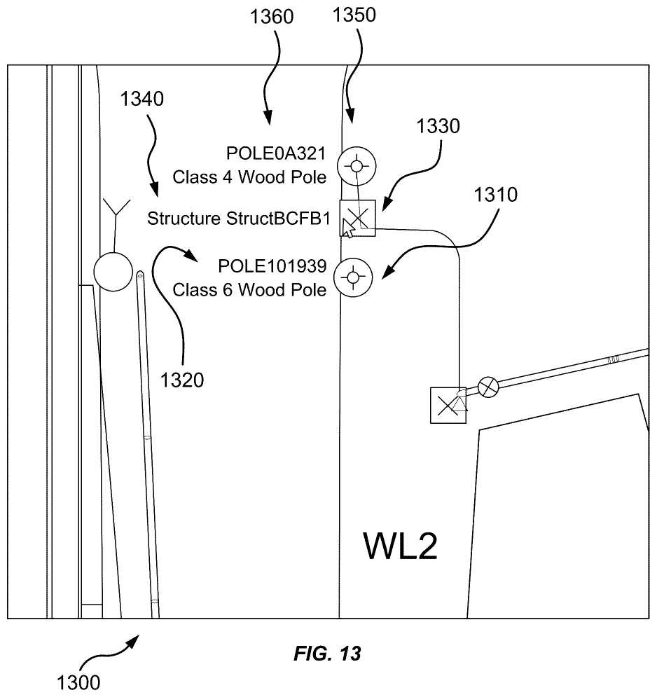

FIG. 13 illustrates a partial layout (e.g., view) providing label information for a plurality of objects according to aspects of the present disclosure. The interface 1300 depicts a portion of a layout of a work location. The interface 1300 includes an example having three objects indicated as three respective symbols via the interface 10, which have been selected to have label information visually displayed on the layout. This includes a first object 1310 (e.g., a utility pole designated for removal) which has been selected to visualize label information 1320, a second object 1330 (e.g., a pedestal designated for installation) which has been selected to visualize label information 1340, and a third object 1350 (e.g., a utility pole designated for installation) which has been selected to visualize label information 1360. As previously noted, each layout may have its own respective label information to be displayed, thus in an output 1000 having a plurality of layouts, one or more of the label information 1320, 1340, and/or 1360 might not be displayed at a separate layout or may be included without departing from the spirit and scope of the present disclosure.

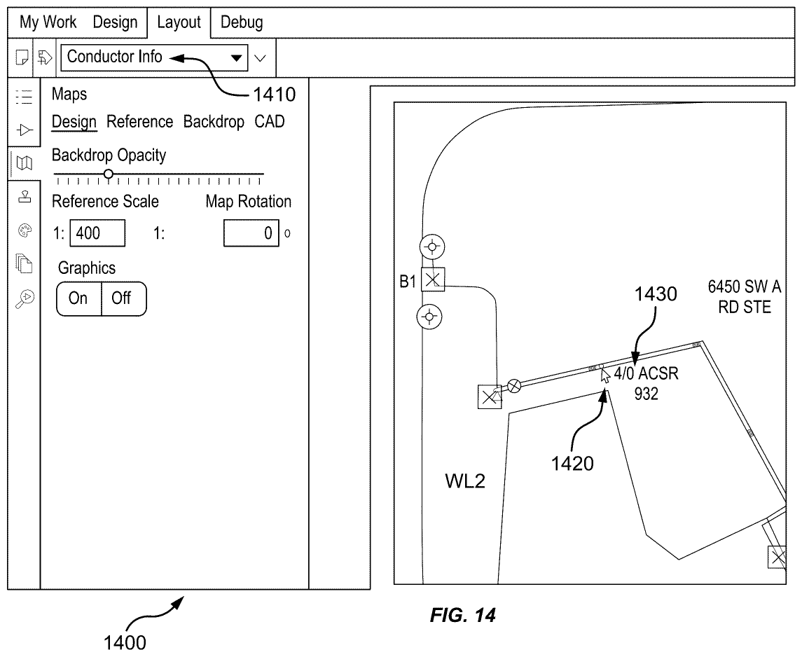

FIG. 14 illustrates a partial view of an example of an interface usable according to aspects of the present disclosure. The interface 1400 includes a first label set selected at the menu 1410. In the embodiment illustrated by FIG. 14, a conductor information label set has been selected by a user. The user is enabled to select placement of the label information using a selector 1420 (e.g., a mouse click), which provides the label information 1430 associated with an object on the interface (in the case of FIG. 14, a conductor).

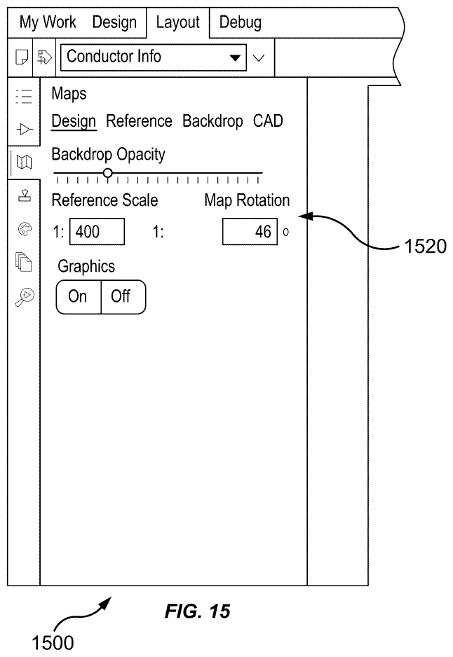

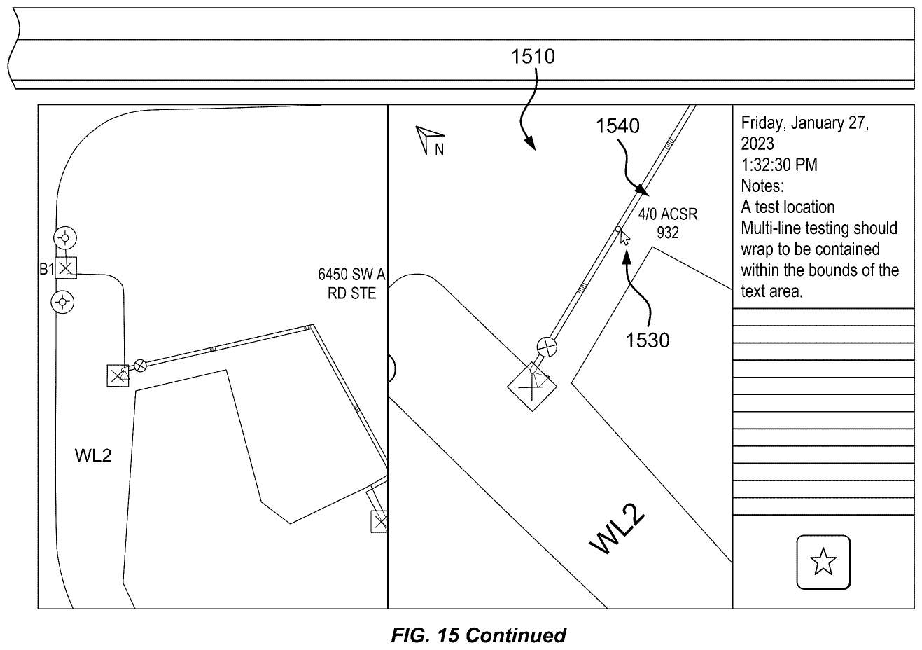

FIG. 15 illustrates a partial view of an example of an interface for customizing one or more layouts according to aspects of the present disclosure. The interface 1500 includes two layouts. The right-side layout 1510 includes a rotated map view relative to the other layout, a rotation angle of which may be specified by a user at the map rotation section 1520. The user may select where the label information 1540 is to be placed using the selector 1530 (e.g., mouse pointer). An orientation of the label information 1540 may be determined and/or modified in various embodiments to be oriented vertically relative to the viewer of the layout.

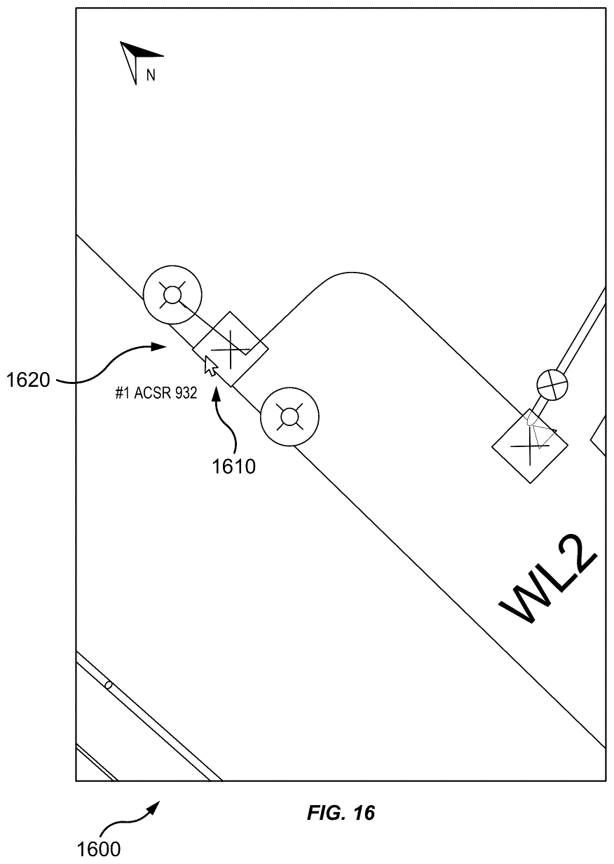

FIG. 16 illustrates a partial view of an example of an interface for customizing one or more layouts according to aspects of the present disclosure. Similar to the embodiment illustrated by FIG. 15, a user of an interface 1600 may select where the label information 1620 is to be placed using the selector 1610 (e.g., mouse pointer). An orientation of the label information 1620 may be determined and/or modified in various embodiments to be oriented vertically relative to the viewer of the layout.

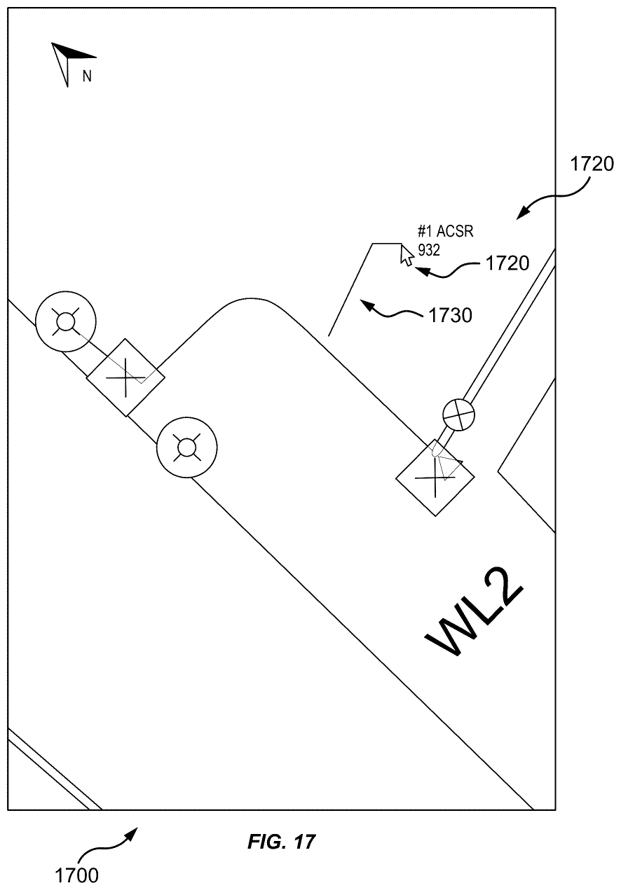

FIG. 17 illustrates as example of a callout associated with label information according to aspects of the present disclosure. The partial interface 1700 reflects a rotated map view where a user is enabled to place the label information 1720 away from an object associated with the label information (in this case, a conductor) using a selector 1710 (e.g., a mouse pointer) which permits the user to visually place the label information. The label information may be visually indicated as relating to the object using one or more visual elements 1730, such as a callout, and arrow, or the like.

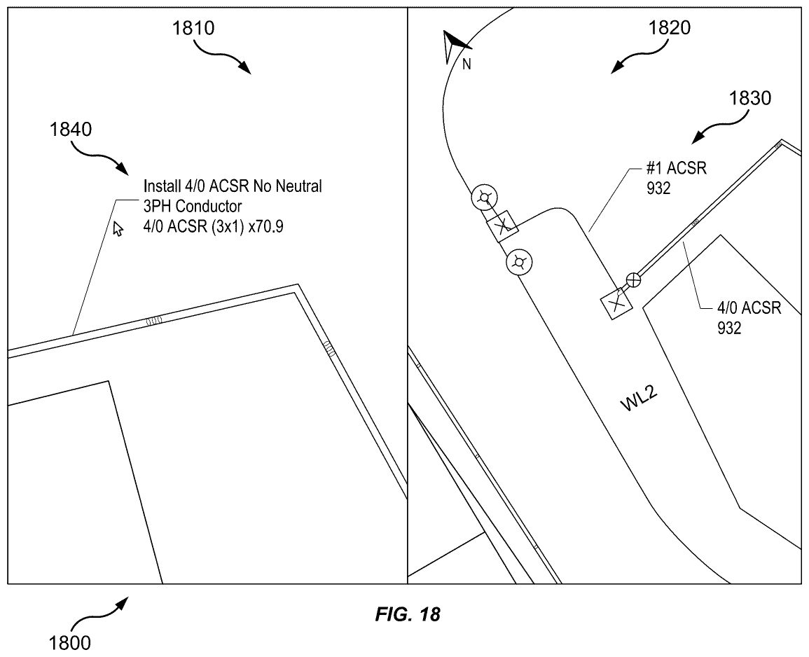

FIG. 18 illustrates an example of a partial multi-layout view of a work location according to aspects of the present disclosure. The multi-layout view 1800 includes a first layout 1810 and a second layout 1820. Although illustrating a same work location, each layout may have different perspective, orientation, identified objects, and different label information displayed therein, as selected by a user. For example, the first layout 1810 includes a zoomed in view of a portion of the work location WL2 and shows label information corresponding to a conductor to be installed at the work location. In contrast, the second layout 1820 includes a more zoomed out view of the work location reflecting a plurality of objects and includes different label information regarding the conductor identified in the first layout 1810, as well as additional label information not identified in the first layout 1810.

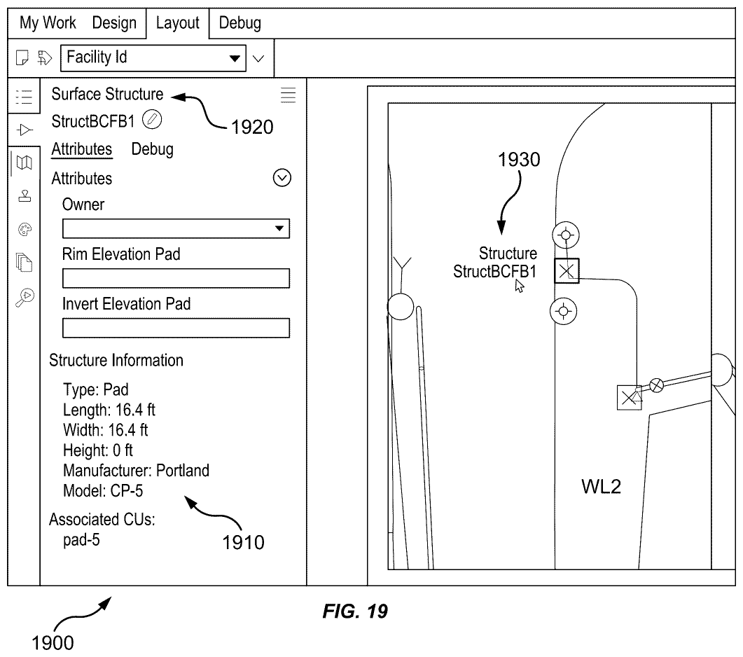

FIG. 19 illustrates an example of a first interface view for manipulating object information according to aspects of the present disclosure. The interface 1900 includes one or more of a structure attribute section 1910 having a structure name section 1920. A layout including label information relating to the object 1930 associated with the structure name section 1920 is provided. A user of a device 110 is enabled to add, delete, and/or modify at least a portion of information and/or metadata relating to an object using the structure attribute section 1910. This includes changing label information concerning the object to be displayed on the layout.

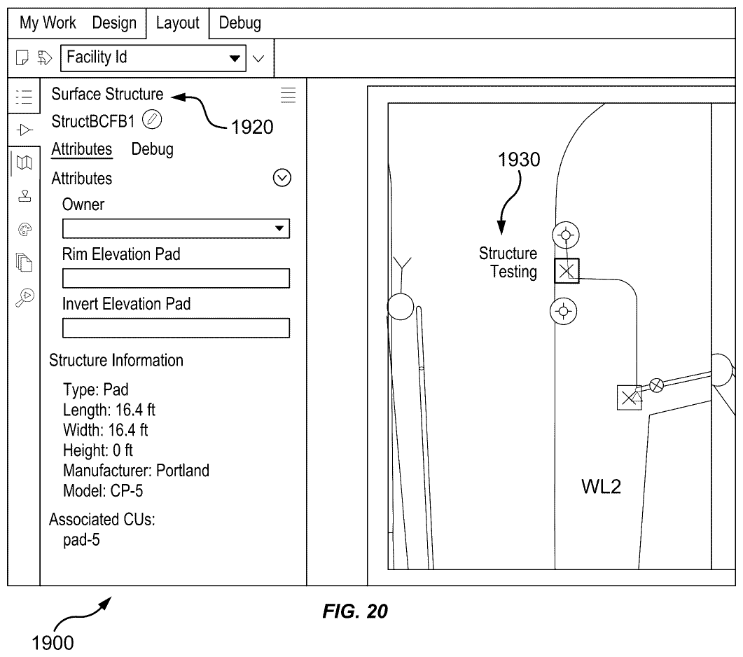

FIG. 20 illustrates an example of a second interface view corresponding to FIG. 19, whereby the structure name has been changed according to aspects of the present disclosure. Relative to the embodiment of FIG. 19, in FIG. 20, a user modifies the structure name section 1920 of the structure attribute section 1910. This change in turn modifies the corresponding object label information and which is propagated to the layout and reflected by the updated object label information on the layout.

Implementations consistent with the present disclosure may enable vector-based prints. Construction prints may be generated according to one or more layouts described herein in the manner disclosed. Existing print issues relating to construction prints may be improved according to aspects described herein, for example in relation to increased speed, increased stability, reducing file sizes, and providing increased consistently in label placement, as compared to existing construction prints. This may be implemented, in whole or in part, using vector-based prints. Vector-based prints provide better control over label placement, better stability, introduction of vector-based graphics across an application, simplification of the number of symbol/label configurations needed, provide a smaller footprint for generated files (e.g., Adobe PDFs generated more quickly, such as in seconds), provide the ability to monitor memory usage, and permit the ability to implement undo/redo for layouts.

According to aspects of the present disclosure, provided is a method of providing assisted generation of label sets and providing information, including obtaining label definition information, selecting a subset of the label definition information, associating the subset of the label definition information with at least one scenario labeling set, providing a map view to a user, obtaining a selection of a chosen scenario labeling set of the at least one scenario labeling sets, determine placement of at least one label of the chosen scenario labeling set on the map view provided to the user, associating the at least one label with at least one attribute, and updating the map view responsive to the associating the at least one label with the at least one attribute. The at least one attribute may include one or more of symbol information, data, or mapping information. The method may include selectively enabling movement or deletion of the at least one label on the map view. The method may include updating an orientation, size, or placement of the at least one label defined by a respective label definition information when a scale or orientation of the map view is changed. The method may include generating a construction print corresponding to the updated map view.

According to further aspects of the present disclosure, provided is a device for providing assisted generation of label sets, the system including a processor, a memory, a communication section communicatively coupleable to the network, and an interface configured to enable one or more operations using the processor and the memory, including obtaining label definition information, selecting a subset of the label definition information, associating the subset of the label definition information with at least one scenario labeling set, providing a map view to a user, obtaining a selection of a chosen scenario labeling set of the at least one scenario labeling sets, determine placement of at least one label of the chosen scenario labeling set on the map view provided to the user, associating the at least one label with at least one attribute, and updating the map view responsive to the associating the at least one label with the at least one attribute. The at least one attribute may include one or more of symbol information, data, or mapping information. The interface may enable movement or deletion of the at least one label on the map view. The interface may further enable updating an orientation, size, or placement of the at least one label defined by a respective label definition information when a scale or orientation of the map view is changed.

According to still further aspects of the present disclosure, provided is a non-transitory computer-readable medium storing an information system program including instructions that, when executed by a processor of a device, causes the device to perform the operations of obtaining label definition information, selecting a subset of the label definition information, associating the subset of the label definition information with at least one scenario labeling set, providing a map view to a user, obtaining a selection of a chosen scenario labeling set of the at least one scenario labeling sets, determine placement of at least one label of the chosen scenario labeling set on the map view provided to the user, associating the at least one label with at least one attribute, and updating the map view responsive to the associating the at least one label with the at least one attribute. The at least one attribute includes one or more of symbol information, data, or mapping information. The non-transitory computer-readable medium may include one or more operations for selectively enabling movement or deletion of the at least one label on the map view. An orientation, size, or placement of the at least one label defined by a respective label definition information may be updated when a scale or orientation of the map view is changed. A construction print may be generated corresponding to the updated map view.

Details of an exemplary computing system that may be used to implement various embodiments of this disclosure is described below. In general, any general-purpose computer systems used in various embodiments of this disclosure may be, for example, general-purpose computers such as those based on Intel® Pentium-type processor, Motorola® PowerPC, Sun® UltraSPARC®, Hewlett-Packard® PA-RISC processors, or any other type of processor. Such computer systems may be either physical or virtual.

For example, various embodiments of the disclosure may be implemented as specialized software executing in a general-purpose computer system. The computer system may include a processor connected to one or more memory devices, such as a disk drive, memory, or other device for storing data. Memory is typically used for storing programs and data during operation of the computer system. The computer system may also include a storage system that provides additional storage capacity. Components of computer system may be coupled by an interconnection mechanism, which may include one or more busses (e.g., between components that are integrated within the same machine and/or a network (e.g., between components that reside on separate discrete machines). The interconnection mechanism enables communications (e.g., data, instructions) to be exchanged between system components of system.

Computer system also includes one or more input devices, for example, a keyboard, mouse, trackball, microphone, touch screen, and one or more output devices, for example, a printing device, display screen, speaker. In addition, computer system may contain one or more interfaces (not shown) that connect computer system to a communication network (in addition or as an alternative to the interconnection mechanism).

The storage system typically includes a computer readable and writeable nonvolatile recording medium in which signals are stored that define a program to be executed by the processor or information stored on or in the medium to be processed by the program to perform one or more functions associated with embodiments described herein. The medium may, for example, be a disk or flash memory. Typically, in operation, the processor causes data to be read from the nonvolatile recording medium into storage system memory that allows for faster access to the information by the processor than does the medium. This storage system memory is typically a volatile, random-access memory such as a dynamic random-access memory (DRAM) or static memory (SRAM). This storage system memory may be located in storage system, as shown, or in the system memory. The processor generally manipulates the data within the memory system and then copies the data to the medium after processing is completed. A variety of mechanisms are known for managing data movement between the medium and the integrated circuit memory element, and the disclosure is not limited thereto. The disclosure is not limited to a particular memory, memory type or storage system.

The computer system may include specially programmed, special-purpose hardware, for example, an application-specific integrated circuit (ASIC). Aspects of the disclosure may be implemented in software, hardware or firmware, or any combination thereof. Further, such methods, acts, systems, system elements and components thereof may be implemented as part of the computer system described above or as an independent component.

Although computer system is shown by way of example as one type of computer system upon which various aspects of the disclosure may be practiced, it should be appreciated that aspects of the disclosure are not limited to being implemented on the computer system. Various aspects of the disclosure may be practiced on one or more computers having a different architecture or components. Further, where functions or processes of embodiments of the disclosure are described herein (or in the claims) as being performed on a processor or controller, such description is intended to include systems that use more than one processor or controller to perform the functions.

Computer system may be a general-purpose computer system that is programmable using a high-level computer programming language. Computer system may be also implemented using specially programmed, special purpose hardware. In computer system, processor is typically a commercially available processor such as the well-known Pentium class processor available from the Intel Corporation. Many other processors are available. Such a processor usually executes an operating system which may be, for example, the Windows 95, Windows 98, Windows NT, Windows 2000, Windows ME, Windows XP, Vista, Windows 7, Windows 10, or progeny operating systems available from the Microsoft Corporation, MAC OS System X, or progeny operating system available from Apple Computer, the Solaris operating system available from Sun Microsystems, UNIX, Linux (any distribution), or progeny operating systems available from various sources. Many other operating systems may be used.

The processor and operating system together define a computer platform for which application programs in high-level programming languages are written. It should be understood that embodiments of the disclosure are not limited to a particular computer system platform, processor, operating system, or network. Also, it should be apparent to those skilled in the art that the present disclosure is not limited to a specific programming language or computer system. Further, it should be appreciated that other appropriate programming languages and other appropriate computer systems could also be used.

In the preceding, reference is made to various embodiments. However, the scope of the present disclosure is not limited to the specific described embodiments. Instead, any combination of the described features and elements, whether related to different embodiments or not, is contemplated to implement and practice contemplated embodiments Furthermore, although embodiments may achieve advantages over other possible solutions or over the prior art, whether or not a particular advantage is achieved by a given embodiment is not limiting of the scope of the present disclosure. Thus, the preceding aspects, features, embodiments, and advantages are merely illustrative and are not considered elements or limitations of the appended claims except where explicitly recited in a claim(s).

It will be appreciated that the development of an actual commercial application incorporating aspects of the disclosed embodiments will require many implementation specific decisions to achieve a commercial embodiment. Such implementation specific decisions may include, and likely are not limited to, compliance with system related, business related, government related and other constraints, which may vary by specific implementation, location and from time to time. While a developer's efforts might be considered complex and time consuming, such efforts would nevertheless be a routine undertaking for those of skill in this art having the benefit of this disclosure.

It should also be understood that the embodiments disclosed and taught herein are susceptible to numerous and various modifications and alternative forms. Thus, the use of a singular term, such as, but not limited to, “a” and the like, is not intended as limiting of the number of items. Similarly, any relational terms, such as, but not limited to, “top,” “bottom,” “left,” “right,” “upper,” “lower,” “down,” “up,” “side,” and the like, used in the written description are for clarity in specific reference to the drawings and are not intended to limit the scope of the invention.

This disclosure is not limited in its application to the details of construction and the arrangement of components set forth in the following descriptions or illustrated by the drawings. The disclosure is capable of other embodiments and of being practiced or of being carried out in various ways. Also, the phraseology and terminology used herein is for the purpose of descriptions and should not be regarded as limiting. The use of “including,” “comprising,” “having,” “containing,” “involving,” and variations herein, are meant to be open-ended, i.e., “including but not limited to.”

The various embodiments disclosed herein may be implemented as a system, method, or computer program product. Accordingly, aspects may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects may take the form of a computer program product embodied in one or more computer-readable medium(s) having computer-readable program code embodied thereon.

Any combination of one or more computer-readable medium(s) may be utilized. The computer-readable medium may be a non-transitory computer-readable medium. A non-transitory computer-readable medium may be, for example, but not limited to, an electronic, magnetic, optical, electromagnetic, infrared, or semiconductor system, apparatus, or device, or any suitable combination of the foregoing. More specific examples (a non-exhaustive list) of the non-transitory computer-readable medium can include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. Program code embodied on a computer-readable medium may be transmitted using any appropriate medium, including but not limited to wireless, wireline, optical fiber cable, RF, etc., or any suitable combination of the foregoing.

Computer program code for carrying out operations for aspects of the present disclosure may be written in any combination of one or more programming languages. Moreover, such computer program code can execute using a single computer system or by multiple computer systems communicating with one another (e.g., using a local area network (LAN), wide area network (WAN), the Internet, etc.). While various features in the preceding are described with reference to flowchart illustrations and/or block diagrams, a person of ordinary skill in the art will understand that each block of the flowchart illustrations and/or block diagrams, as well as combinations of blocks in the flowchart illustrations and/or block diagrams, can be implemented by computer logic (e.g., computer program instructions, hardware logic, a combination of the two, etc.). Generally, computer program instructions may be provided to a processor(s) of a general-purpose computer, special-purpose computer, or other programmable data processing apparatus. Moreover, the execution of such computer program instructions using the processor(s) produces a machine that can carry out a function(s) or act(s) specified in the flowchart and/or block diagram block or blocks.

One or more portions of the computer system may be distributed across one or more computer systems coupled to a communications network. For example, as discussed above, a computer system that determines available power capacity may be located remotely from a system manager. These computer systems also may be general-purpose computer systems. For example, various aspects of the disclosure may be distributed among one or more computer systems configured to provide a service (e.g., servers) to one or more client computers, or to perform an overall task as part of a distributed system. For example, various aspects of the disclosure may be performed on a client-server or multi-tier system that includes components distributed among one or more server systems that perform various functions according to various embodiments of the disclosure. These components may be executable, intermediate (e.g., IL) or interpreted (e.g., Java) code which communicate over a communication network (e.g., the Internet) using a communication protocol (e.g., TCP/IP). For example, one or more database servers may be used to store device data, such as expected power draw, that is used in designing layouts associated with embodiments of the present disclosure.

It should be appreciated that the disclosure is not limited to executing on any particular system or group of systems. Also, it should be appreciated that the disclosure is not limited to any particular distributed architecture, network, or communication protocol.

Various embodiments of the present disclosure may be programmed using an object-oriented programming language, such as SmallTalk, Java, C++, Ada, or C# (C-Sharp). Other object-oriented programming languages may also be used. Alternatively, functional, scripting, and/or logical programming languages may be used, such as BASIC, Fortran, Cobol, TCL, or Lua. Various aspects of the disclosure may be implemented in a non-programmed environment (e.g., analytics platforms, or documents created in HTML, XML, or other format that, when viewed in a window of a browser program render aspects of a graphical-user interface (GUI) or perform other functions). Various aspects of the disclosure may be implemented as programmed or non-programmed elements, or any combination thereof.

The flowchart and block diagrams in the Figures illustrate the architecture, functionality and/or operation of possible implementations of various embodiments of the present disclosure. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

It is to be understood that the above description is intended to be illustrative, and not restrictive. Many other implementation examples are apparent upon reading and understanding the above description. Although the disclosure describes specific examples, it is recognized that the systems and methods of the disclosure are not limited to the examples described herein but may be practiced with modifications within the scope of the appended claims. Accordingly, the specification and drawings are to be regarded in an illustrative sense rather than a restrictive sense. The scope of the disclosure should, therefore, be determined with reference to the appended claims, along with the full scope of equivalents to which such claims are entitled.

1. A method of providing assisted generation of label sets and providing information, comprising:
obtaining label definition information;
selecting a subset of the label definition information;
associating the subset of the label definition information with at least one scenario labeling set;
providing a map view to a user;
obtaining a selection of a chosen scenario labeling set of the at least one scenario labeling sets;
determine placement of at least one label of the chosen scenario labeling set on the map view provided to the user;
associating the at least one label with at least one attribute; and
updating the map view responsive to the associating the at least one label with the at least one attribute.

2. The method of claim 1, wherein the at least one attribute includes one or more of symbol information, data, or mapping information.

3. The method of claim 1, further comprising:
enabling movement or deletion of the at least one label on the map view.

4. The method of claim 1, further comprising updating an orientation, size, or placement of the at least one label defined by a respective label definition information when a scale or orientation of the map view is changed.

5. The method of claim 1, further comprising generating a construction print corresponding to the updated map view.

6. A device for providing assisted generation of label sets, the device comprising:
a processor;
a memory;
a communication section communicatively coupleable to a communication network;
an interface provided at the device, the interface configured to perform one or more operations using the processor and the memory, the operations including,
obtaining label definition information;
selecting a subset of the label definition information;
associating the subset of the label definition information with at least one scenario labeling set;
providing a map view to a user;
obtaining a selection of a chosen scenario labeling set of the at least one scenario labeling sets;
determine placement of at least one label of the chosen scenario labeling set on the map view provided to the user;
associating the at least one label with at least one attribute; and
updating the map view responsive to the associating the at least one label with the at least one attribute.

7. The device of claim 6, wherein the at least one attribute includes one or more of symbol information, data, or mapping information.

8. The device of claim 6, wherein the interface is further configured to enable movement or deletion of the at least one label on the map view.

9. The device of claim 6, further comprising updating an orientation, size, or placement of the at least one label defined by a respective label definition information when a scale or orientation of the map view is changed.

10. A non-transitory computer-readable medium storing an information system program including instructions that, when executed by a processor of a device, causes the device to perform operations of:
obtaining label definition information;
selecting a subset of the label definition information;
associating the subset of the label definition information with at least one scenario labeling set;
providing a map view to a user;
obtaining a selection of a chosen scenario labeling set of the at least one scenario labeling sets;
determine placement of at least one label of the chosen scenario labeling set on the map view provided to the user;
associating the at least one label with at least one attribute; and
updating the map view responsive to the associating the at least one label with the at least one attribute.

11. The non-transitory computer-readable medium of claim 10, wherein the at least one attribute includes one or more of symbol information, data, or mapping information.

12. The non-transitory computer-readable medium of claim 10, further comprising:
selectively enabling movement or deletion of the at least one label on the map view.

13. The non-transitory computer-readable medium of claim 10, further comprising updating an orientation, size, or placement of the at least one label defined by a respective label definition information when a scale or orientation of the map view is changed.

14. The non-transitory computer-readable medium of claim 10, further comprising generating a construction print corresponding to the updated map view.
